(19) United States
(12) Patent Application Publication
(10) Pub. No.: US 2011/0033638 A1
(43) Pub. Date: Feb. 10, 2011

(54) METHOD AND APPARATUS FOR DEPOSITION ON LARGE AREA SUBSTRATES HAVING REDUCED GAS USAGE

(75) Inventors: Hari Ponnekanti, San Jose, CA (US); Randhir Thakur, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/538,682

(22) Filed: Aug. 10, 2009

(51) Int. Cl. B01J 19/08; C23C 16/54

(52) U.S. Cl. 427/569; 118/723 E

(57) ABSTRACT

A method and apparatus for processing a substrate is described. The apparatus includes a showerhead assembly in a processing chamber. The showerhead assembly is sized to cover a fraction of the length of the substrate. The showerhead assembly includes a first gas channel on a perimeter thereof and a second gas channel in a center thereof. The perimeter gas channel is configured to flow a first gas toward the substrate to form a gas curtain containing a reduced volume processing region between the showerhead and the substrate. Various thermal and/or deposition processes are performed on the substrate within the region interior of the gas curtain.

### BACKGROUND OF THE INVENTION

1. Field of the Invention

Embodiments described herein relate to a method and apparatus for depositing one or more layers on a large area substrate. More specifically, to depositing one or more thin films of material on flat media, such as rectangular, flexible sheets of glass, plastic or other material in the manufacture of flat panel displays, photovoltaic devices or solar cells, among other applications.

2. Description of the Related Art

Photovoltaic (PV) devices or solar cells are devices which convert sunlight into direct current (DC) electrical power. The PV devices are typically formed on thin, flat media having a large surface area. Typically, the flat media includes flexible sheets of glass, plastic or other material. Several types of silicon films, including microcrystalline silicon film (μc-Si), amorphous silicon film (a-Si), polycrystalline silicon film (poly-Si) and the like, are sequentially deposited on the flat media to form the PV devices. A transparent conductive film or a transparent conductive oxide (TCO) film may be deposited in or on these silicon films. The deposition of the thin films on the flat media is typically performed by a chemical vapor deposition (CVD) process, a plasma enhanced chemical vapor deposition (PECVD) process, physical vapor deposition (PVD), among other deposition processes.

In conventional PECVD deposition systems, precursor gases used to form the thin films are flowed through a gas diffusion plate having a perforated surface area equal to or greater than the surface area of the flat media. A plasma is ignited in a processing area between the gas diffusion plate and the substrate to assist in deposition of the thin films on the substrate. The large surface area of the gas diffusion plate and the resulting processing area ensures that the plasma covers the entire surface area of the flat media uniformly.

The conventional deposition systems require large amounts of precursor gases to be delivered in this manner to the processing area. However, much of the precursor gas is not used in the deposition process and the excess precursor gas is flowed to other parts of the chamber volume and/or exhausted. Further, the excess precursor gas may adhere to or react with surfaces within the chamber, which increases cleaning frequency and cleaning gas usage. The use of both of the precursor gases and cleaning gases form byproducts that are typically solids, which may increase the frequency of maintenance of exhaust and abatement systems. Thus, the high gas volume used in these systems and the increased maintenance frequency required by these systems increase the cost of ownership of these systems.

Additionally, typical cleaning processes in the conventional systems use fluorine containing gases delivered through the gas distribution plate to the processing area in the same manner as precursor gases are delivered. As a result, the fluorine containing gases are applied in excess in the conventional systems and a great portion is wasted. Thus, one or both of a combination of wasted cleaning gas, and the enhanced environmental and safety threat posed by using large amounts of fluorine containing gases, increase the cost of ownership of the conventional systems.

Therefore, what is needed is an apparatus and method for supplying gas to a processing area that requires less gas than the conventional systems and utilizes the gas at a high rate, while also limiting excess gas in other portions of the chamber.

### SUMMARY OF THE INVENTION

The present invention generally provides a method and apparatus for processing a substrate. In one embodiment, an apparatus for forming thin films is described. The apparatus includes a chamber defining an interior volume, and at least two showerhead assemblies movably coupled to the chamber within the interior volume opposing a movable substrate support surface, each of the showerhead assemblies being coupled to an actuator providing movement of the respective showerhead assembly in a first linear direction relative to the movable substrate support surface, each of the showerhead assemblies comprising an inner gas channel and an outer gas channel surrounding and separated from the inner gas channel, each of the inner gas channels and outer gas channels having a plurality of openings formed therein, the openings in the inner gas channels being directed toward the substrate support surface to deliver a first gas, and the openings in the outer gas channel being oriented to direct a second gas toward the substrate support surface and completely enclose the first gas.

In another embodiment, an apparatus for forming thin films on flexible media is described. The apparatus includes a chamber having at least two showerhead assemblies movably coupled to an interior of the chamber, each of the at least two showerhead assemblies being coupled to a first linear motion assembly to move the respective showerhead assemblies in a Z direction, each of the showerhead assemblies comprising an inner gas channel and an outer gas channel surrounding and separated from the inner gas channel, each of the inner gas channels and outer gas channels having a plurality of openings formed therein, the openings in the inner gas channels being directed toward the flexible media to deliver a first gas, and the openings in the outer gas channel being oriented to direct a second gas toward the flexible media and completely surround the first gas, and a movable substrate support surface disposed within the interior of the chamber in an opposing relationship to the at least two showerhead assemblies, the movable substrate support surface comprising a plurality of rollers to receive and support at least a portion of the flexible media and defining a linear substrate travel path in the X direction to move the flexible media relative to the at least two showerhead assemblies.

In another embodiment, a method for processing a substrate is described. The method includes transferring a substrate to a processing chamber having an internal volume consisting of a first environment, flowing a first gas from a perimeter of a first showerhead assembly to form a processing region on a portion of the substrate, the processing region comprising a second environment that is substantially isolated from the first environment, flowing a second gas from a center of the first showerhead assembly to an area interior of the processing region to deposit a first thin film on the substrate, and moving the substrate in a first linear direction relative to the first showerhead assembly to deposit the first thin film on other portions of the substrate.

In another embodiment, a method for processing a portion of a substrate is described. The method includes transferring a substrate to a processing chamber having a movable support surface adapted to move the first substrate in a first linear direction, depositing a first thin film on a portion of the substrate with a first showerhead assembly disposed in the processing chamber, the first showerhead assembly movable in a second linear direction that is substantially normal to the first linear direction, moving the substrate in the first linear direction relative to the first showerhead assembly, and altering the first thin film with a second showerhead assembly disposed in the processing chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a side cross-sectional view of one embodiment of a processing chamber.

FIG. 2 is a cross-sectional view of the processing chamber taken along lines 2A-2A of FIG. 1.

FIG. 3A is a schematic side cross-sectional view of one embodiment of a showerhead assembly.

FIG. 3B is a bottom view of the showerhead assembly 360 illustrated in FIG. 3A.

FIG. 4A is a schematic side cross-sectional view of another embodiment of a showerhead assembly.

FIG. 4B is an exploded cross-sectional view of a portion of the showerhead assembly of FIG. 4A.

FIG. 4C is a schematic bottom view of the showerhead assembly taken along lines 4C-4C of FIG. 4B.

FIG. 4D is a schematic cross-sectional view of another embodiment of a showerhead assembly.

FIG. 4E is a side view of the showerhead assembly shown in FIGS. 4A and 4B showing one embodiment of an insulating member.

FIG. 5A is a schematic side cross-sectional view of another embodiment of a showerhead assembly.

FIG. 5B is a schematic side view of one embodiment of an energy emitting device of FIG. 5A.

FIG. 6 is a schematic side cross-sectional view of one embodiment of a pass-by substrate processing apparatus utilizing two showerhead assemblies.

FIG. 7 is a flowchart of one embodiment of a substrate processing method.

FIG. 8 is a flowchart of another embodiment of a substrate processing method.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION

Embodiments described herein relate to a method and an apparatus for processing a substrate or flexible media having at least one major surface or side with a large surface area. Although the flexible media is described herein as a discrete sheet, some embodiments may be utilized with flat media dispensed from a supply roll. Embodiments of a processing chamber adapted to deposit materials on the major surface of the flat media is described herein. In one aspect, the processing chamber may be part of a larger processing system having multiple processing chambers disposed in a modular, sequential arrangement in a fabrication facility. The modular arrangement may be an in-line configuration or a cluster tool configuration. An example of a larger processing system may be found in U.S. patent application Ser. No. 12/202,199, filed Aug. 29, 2008, which is incorporated herein by reference. Examples of commercial apparatus that may benefit from embodiments described herein is the Applied ATON™ deposition system and the AKT® 55K, 60K or 90K PECVD systems available from Applied Materials, Inc., of Santa Clara, Calif.

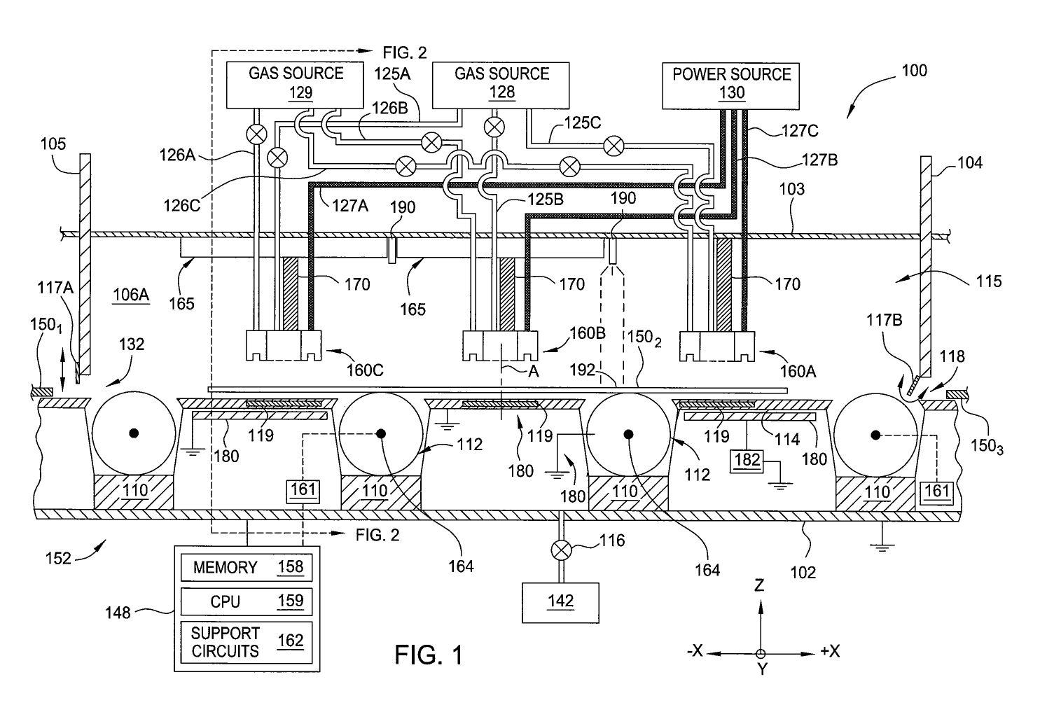

FIG. 1 is a side cross-sectional view of one embodiment of a processing chamber 100 that is part of a larger system used to fabricate photovoltaic devices, liquid crystal displays (LCD's), flat panel displays, or organic light emitting diodes (OLED's). The processing chamber 100 is configured to serially process a plurality of substrates 150ₙ using thermal processes or a plasma enhanced chemical vapor deposition (CVD) process to form structures and devices on the substrates 150ₙ. In one embodiment, the structures may include one or more junctions used to form part of a thin film photovoltaic device or solar cell. In another embodiment, the structures may be a part of a thin film transistor (TFT) used to form a LCD or TFT type device.

The plurality of substrates 150ₙ are shown as substrates 150₁, 150₂ and 150₃ (only a portion of the substrates 150₁ and 150₂ are shown) that are placed, conveyed or otherwise transferred to or through an internal volume 115, within the processing chamber 100. Each of the substrates 150₁, 150₂ and 150₃ may be thin sheet of metal, plastic, organic material, silicon, glass, quartz, or polymeric materials, among other suitable materials. In one embodiment, the substrates 150₁, 150₂ and 150₃ have a surface area on a major side that is greater than about 1 square meter, such as greater than about 2 square meters.

The processing chamber 100 is generally a rectangular shaped enclosure having a bottom 102, a top 103, a front wall 104, a back wall 105, and sidewalls 106A, 106B (only 106A is shown in this view) enclosing the internal volume 115. The front wall 104 includes a first substrate transfer port 118 and the back wall 105 includes a second substrate transfer port 132 that facilitates substrate entry and exit from the processing chamber 100. The first transfer port 118 and the second transfer port 132 include a sealable door 117A and/or 117B, which may be slit valves that can be selectively opened for transfer or closed to maintain subatmospheric pressure, or negative pressure, within the internal volume 115 of the processing chamber 100. The transfer ports 118, 132 may be coupled to a transfer chamber (e.g., substrate transferring region), a load lock chamber (e.g., interface to an environment having a different pressure or gas composition) and/or other process chambers (e.g., PVD chamber, CVD chamber) of a substrate processing system. In one embodiment, at least one of the walls 104, 105 may also be a wall that is shared with a transfer chamber, a load lock chamber and/or other process chambers as part of an in-line system or a cluster tool configuration. Typically, at least one of the bottom 102 and one or more of the walls 104, 105, 106A, 106B is electrically grounded.

In one embodiment of the invention, the processing chamber 100 comprises one or more showerhead assemblies, such as showerhead assemblies 160A-160C shown in FIG. 1. Each of the showerhead assemblies 160A-160C are utilized to perform a process on the surface of a substrate by providing a processing region or an internal zone that is selectively isolated from the internal volume 115. The processing region or internal zone is generally provided by a purge gas flowed toward the substrate from a perimeter of the individual showerhead assemblies. The processes performed by each of the showerhead assemblies 160A-160C include forming one or more layers of material on the surface of the substrate, altering materials and/or properties of materials on the surface of the substrate, and combinations thereof. In one embodiment, one or more of the showerhead assemblies 160A-160C are utilized to provide reactive gases to the surface of the substrate disposed in the internal volume 115 to form a layer of material thereon. In another embodiment, one or more of the showerhead assemblies 160A-160C are adapted to perform a thermal process on the substrate to alter a layer or layers of previously deposited material.

Each of the showerhead assemblies 160A-160C may be configured to deposit a variety of materials on the substrates 150₁, 150₂ and 150₃ including, but not limited to, dielectric materials (e.g., SiO₂, SiOₓN_{y}, derivatives thereof or combinations thereof), semiconductor materials (e.g., intrinsic silicon, doped silicon, silicon germanium, germanium), specialized coatings (e.g., SiN_{X}, SiOₓN_{y} or derivatives thereof), or transparent conductive oxide layers (e.g., zinc oxide (ZnO), tin oxide (SnO), AZO). Specific examples of materials that are formed or deposited by the components in the processing chamber 100 onto the substrates 150₁, 150₂ and 150₃ may include amorphous silicon, microcrystalline silicon, epitaxial silicon, polycrystalline silicon, silicon dioxide, silicon oxynitride, silicon nitride, zinc oxide, and/or tin oxide that may be doped (e.g., B, P, or As), or undoped. Each of the showerhead assemblies 160A-160C are also configured to receive and distribute gases such as argon (Ar), hydrogen (H₂), nitrogen (N₂), helium (He), or combinations thereof, for use as a purge gas or a carrier gas. One example of depositing silicon thin films on the substrates 150₁, 150₂ and 150₃ using the processing chamber 100 may be accomplished by using silane as the precursor gas in a hydrogen carrier gas.

While three showerhead assemblies 160A, 160B and 160C are shown in the internal volume 115 of FIG. 1, this configuration is not intended to limiting as to the scope of the invention, since only one or two showerhead assemblies may be positioned in the internal volume 115 without deviating from the basic scope of the invention. Additional showerhead assemblies in excess of the showerhead assemblies 160A, 160B and 160C (not shown) may also be utilized to achieve a desire substrate throughput and/or form a deposited layer having different characteristics (e.g., thickness, uniformity, composition). Additionally, while three showerhead assemblies 160A, 160B and 160C are shown in the internal volume 115, only one, two or three showerhead assemblies may be utilized during the processing of any one or all of the substrates 150₁, 150₂ and 150₃.

A controller 148 having a memory 158, a central processing unit (CPU) 159 and support circuits 162 is coupled to the processing chamber 100. The controller 148 is utilized to control the process sequence, regulating the gas flows from a primary gas source 128, a secondary gas source 129 and power delivered from a power source 130 to one or more of the showerhead assemblies 160A-160C disposed in the processing chamber 100. The CPU 159 may be of any form of a general purpose computer processor that can be used in an industrial setting. The software routines can be stored in the memory 158, such as random access memory, read only memory, floppy or hard disk drive, or other form of digital storage. The support circuits 162 are conventionally coupled to the CPU 159 and may comprise cache, clock circuits, input/output subsystems, power supplies, and the like. The software routines may also be stored and/or executed by a second controller (not shown) that is located remotely from the processing chamber 100.

The primary gas source 128 is adapted to deliver a processing gas which may include an inert gas, a non-reactive gas or a reactive gases and combinations thereof. Each of the gases may be derived from a solid source, a liquid source or a vapor source and provided to the processing chamber 100 in a gaseous form. Examples of processing gases that may be provided by the primary gas source 128 include argon (Ar), helium (He), nitrogen (N₂), oxygen (O₂), hydrogen (H₂), nitrogen dioxide (NO₂), nitrous oxide (N₂O), silane (SiH₄), disilane (Si₂H₆), silicon tetrafluoride (SiF₄), silicon tetrachloride (SiCl₄), dichlorosilane (SiH₂Cl₂), trimethylboron (TMB (or B(CH₃)₃)), diborane (B₂H₆), BF₃, B(C₂H₅)₃, phoshine (PH₃), methane, or combinations thereof and derivatives thereof, as well as other complex precursor gases.

A substrate carrier system 152 is at least partially disposed in the processing chamber 100 to support and convey the substrates 150ₙ to, from and through the internal volume 115. In one embodiment, the substrate carrier system 152 is disposed on the bottom 102 of the processing chamber 100 and includes a plurality of rollers 112. The substrate carrier system 152 also includes a plurality of cover panels 114 disposed among the plurality of rollers 112. A top portion of the plurality of rollers 112 is exposed to the internal volume 115 between the cover panels 114. In one embodiment, the exposed portion of the plurality of rollers 112 define a movable substrate support plane that supports and transfers the substrates 150ₙ above the cover panels 114. The rollers 112 are thus adapted to move a substrate either independently or synchronously relative to the one or more showerhead assemblies 160A, 160B and 160C.

In one embodiment, the rollers 112 of the substrate carrier system 152 are adapted to position the substrate 150₂ in the internal volume 115 of the processing chamber 100 through the first transfer port 118. During processing, as the substrate 150₂ is moved through the internal volume 115, at least one of the showerhead assemblies 160A, 160B, 160C is used to deposit a layer of material on the substrate 150₂ by delivering a reactive gas from the primary gas source 128. Each of the plurality of rollers 112 may be rotated clockwise or counter-clockwise to move the substrate 150₂ in a −X direction or a +X direction. In one embodiment, the substrate 150₂ is advanced over the cover panels 114 by the rollers 112 in the −X direction as a gas is delivered to a surface of the substrate 150₂ from one of the showerhead assemblies 160A, 160B or 160C flowing in a direction A. In one configuration, the gas flow direction A is parallel to a Z direction that is orthogonal to the X direction. In another configuration, the gas flow direction A is provided at an angle (not shown) to the Z direction.

In one embodiment, each of the rollers 112 may be fabricated from an insulative material, such as glass, a polymer, a plastic, and polyphenylene sulfide (PPS) polyetheretherketone (PEEK), a ceramic material or a metallic material, such as aluminum, stainless steel, nickel or metallic alloys, among others. At least a portion of the plurality of rollers 112 may be coupled to and actuated by one or more motors or drives 161 to rotate the rollers 112 about an axis 164. At least one of the drives 161 is coupled to the controller 148 that is adapted to control the rotational movement of one or more of the rollers 112. A heat source 119 adapted to heat the substrate 150₂ may be disposed in the substrate carrier system 152, such as in or on one or more of the cover panels 114. The heat source 119 may be adapted to heat the substrate 150₂ by radiant, convective or conductive type heating methods. The heat source 119 may be a resistive heater disposed in, below, or on a cover panel 114, or a heat lamp system (not shown), such as infrared lamps, that are disposed in, below or on a cover panel 114. In one embodiment, one or more of the cover panels 114 may be made of a transparent material that allows optical energy to pass therethrough and impinge the substrate 150₂.

In one embodiment, to facilitate plasma processing within the internal volume 115, one or more electrodes may be disposed within the processing chamber 100. The one or more electrodes as described herein are adapted as a path through which electrical current can flow. The one or more electrodes may function as an anode or cathode, or are otherwise maintained at a ground potential. The electrodes as described herein include an electrical return medium as well as an earthen ground. The electrodes may be configured as one or more shunt electrodes 180 disposed within the substrate carrier system 152, such as in or adjacent one or more of the cover panels 114. In this embodiment, the shunt electrodes 180 may be made of a conductive material, such as aluminum, stainless steel or other suitable electrically conductive material.

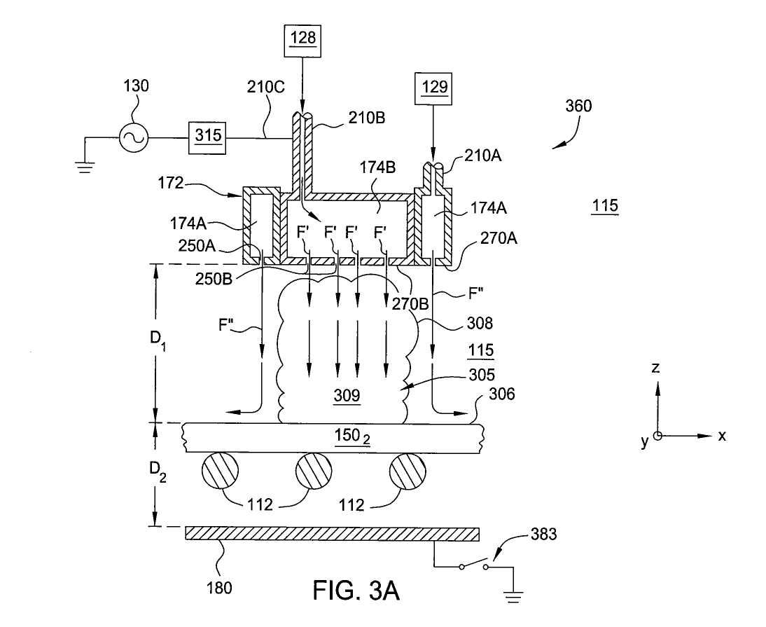

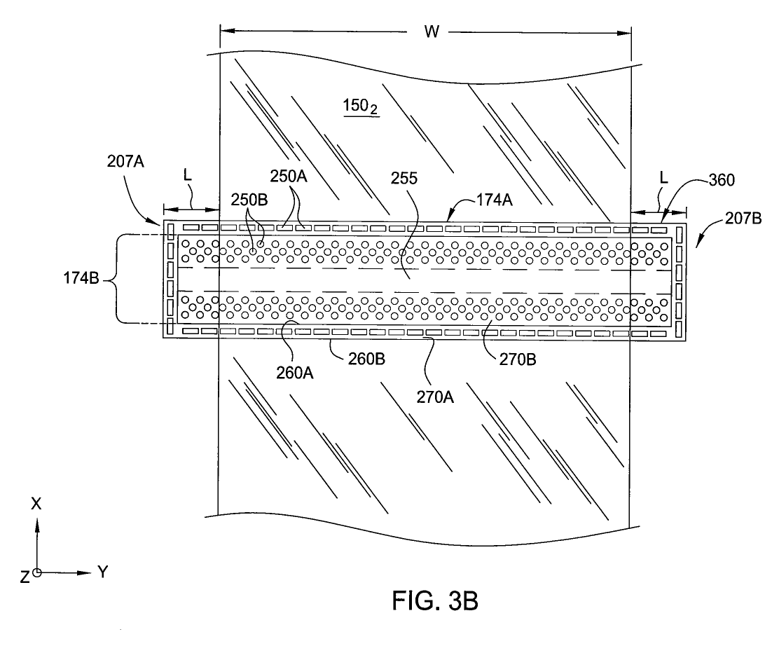

In another embodiment, at least one of the cover panels 114 is adapted as a shunt electrode 180. In this embodiment, the cover panels 114 may house a shunt electrode 180 or be made of a conductive material, such as aluminum, stainless steel or other conductive material. In one embodiment, the shunt electrodes 180 are adapted to function as a RF return path for the RF current generated by an RF generator contained in the power source 130. In another embodiment, at least one of the shunt electrodes 180 may include a power source 182, such as a RF generator enabling the shunt electrode 180 to be RF biased. In one embodiment, the shunt electrode is coupled to a configurable ground 383 (FIG. 3A) having a switching device that may selectively activate and deactivate the grounding capability of the shunt electrode 180.

In one embodiment, one or more of the plurality of rollers 112 may be grounded. In another embodiment, an insulating member 110 is positioned to electrically isolate at least a portion of at least one of the rollers 112 from ground. In this embodiment, the insulating member 110 is configured to support the rollers 112, and thus interrupts an electrical path that may be formed between the rollers 112 and a grounded surface of the processing chamber 100. The substrate 150₂ supported on the electrically isolated rollers 112 will generally electrically float up to the plasma potential during plasma processing. In one embodiment, the insulating member 110 may be in the form of a pad fabricated from an insulating material, such as a ceramic material, rubber, glass, polymer, plastic, polyphenylene sulfide (PPS), polyetheretherketone (PEEK) or any other suitable insulating materials that can withstand the processing conditions maintained in the internal volume 115 during processing and provide insulation between the rollers and the bottom wall 102 of the processing chamber 100.

In one embodiment, each of the showerhead assemblies 160A, 160B and 160C are movable relative to the top 103 and/or the substrate 150₂. For example, each of the showerhead assemblies 160A, 160B and 160C are coupled to a movable support member 170 adapted to move the respective showerhead assembly in at least a first or vertical direction (Z direction) to adjust a distance between the showerhead and the substrate 150₂.

In another embodiment, at least one of the showerhead assemblies 160A, 160B and 160C is coupled to a linear motion assembly 165 (two are shown coupled to showerhead assemblies 160A and 160B). The linear motion assembly 165 is generally adapted to move a showerhead assembly in a second or horizontal direction (X direction). The second direction is substantially orthogonal to the first direction. In one configuration, second direction is aligned parallel to substrate transfer direction.

While the processing chamber 100 is illustrated and has been described above as processing a substrate 150₂ in a horizontal orientation, the invention is not limited to this configuration and may be configured to process the substrate 150₂ in other orientations, such as a vertical orientation. For example, the components in the internal volume 115 may be positioned (corresponding to the orientation of the processing chamber 100 in this view) such that the output face (e.g., reference numeral 270B (FIG. 3A)) of the showerhead assemblies 160A, 160B and 160C and the upper surface (e.g., reference numeral 306 (FIG. 3A)) of the substrate 150₂ are all aligned parallel to the X and Z direction. The substrate 150₂ may be transferred through the internal volume 115 and/or processed in the internal volume 115 by use of, for example, grooved rollers (not shown) or other similar devices that is configured to support the substrate 1502 in a vertical orientation by supporting one or more of the substrates' edges.

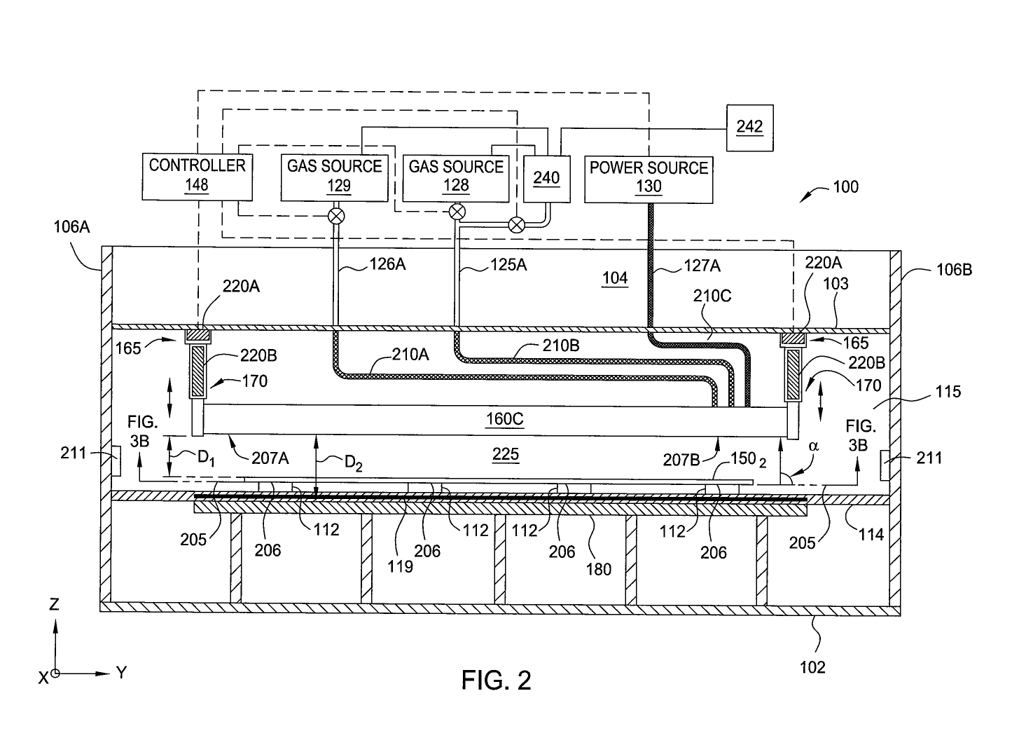

FIG. 2 is a cross-sectional view of the processing chamber 100 taken along lines 2-2 of FIG. 1. The showerhead assembly 160C is coupled to a linear motion assembly 165 and a movable support member 170 to allow movement of the showerhead assembly 160C relative to the top 103 and/or the substrate 150₂. The linear motion assembly 165 includes one or more actuators 220A and the movable support member 170 includes one or more actuators 220B. Each of the actuators 220A, 220B may be a stepper motor, a screw drive and/or a linear motion device powered magnetically, electrically, pneumatically, and combinations thereof. The linear motion assembly 165 controls the position of the showerhead assembly 160C in at least the X-direction while the movable support member 170 controls the position of the showerhead assembly 160C in at least the Z direction. In one embodiment, the actuators utilized in the linear motion assembly 165 and the movable support member 170 are disposed at least partially outside of the internal volume 115. In this embodiment, the actuators included in the linear motion assembly 165 are operably coupled to the showerhead assembly 160C through one or more movable or flexible components (not shown) that transfer motive force to the showerhead assembly 160C. In general, the one or more movable or flexible components may include conventional bellows assemblies or sealed shaft configurations that are adapted to provide translational movement while maintaining a pressure differential between the internal volume 115 and the environment outside of the processing chamber 100.

As shown in FIG. 2, in one embodiment, the movable support member 170 controls a distance D₁ between the lower surface of the showerhead assembly 160C and the substrate 150₂. The distance D₁ between the lower surface of the showerhead assembly 160C and the substrate 150₂ define a processing region 225. The distance D₁ may be adjusted and/or controlled by the system controller 148 and the one or more actuators 220B before, during or after performing a deposition process on the substrate surface. For example, the actuators 220B coupled to the showerhead assembly 160C may be controlled independently or synchronously to vary the distance D₁. The actuators 220B may be controlled to set the distance D₁ prior to a deposition process and/or during a deposition process based on factors such as a spacing between the showerhead assembly 160C and the substrate 150₂ and/or the planarity of the substrate 150₂ during deposition.

In one embodiment, an upper portion of each of the plurality of rollers 112 define a substrate receiving surface 205 that supports and moves the substrate 150₂ through the internal volume 115. The actuators 220B disposed on opposing edges of the showerhead assembly 160C may be controlled to raise or lower respective ends of the showerhead assembly 160C independently relative to the substrate receiving surface 205. In one operational example, the substrate 150₂ may bow or warp in response to thermal forces encountered in the internal volume 115 during processing. In this embodiment, the distance D₁ of the showerhead assembly 160C relative to the substrate 150₂ may be controlled to account for warping of the substrate 150₂.

In one embodiment, the actuators 220B may be controlled to produce a parallel relationship between the showerhead assembly 160C and one or a combination of the substrate receiving surface 205, the substrate 150₂ and the shunt electrode 180. In another embodiment where the substrate receiving surface 205 and the shunt electrode 180 (when present) are substantially parallel, the actuators 220B may be controlled to provide an angle α relative to the substrate receiving surface 205. For example, a first end 207A may be raised or lowered relative to a second end 207B, or vice-versa. In one embodiment, the angle α may be about 80 degrees to about 100 degrees, such as about 90 degrees. In another embodiment, the angle α may be between about 70 degrees to about 110 degrees.

In one embodiment, one or more sensors 211 may be positioned adjacent the substrate 150₂ to monitor the movement of the substrate 150₂ through the internal volume 115. In one aspect, the one or more sensors 211 are directed horizontally (Y direction) across the width of the substrate 150₂. The one or more sensors 211 may be a transmitter/receiver having a light source or beam adapted to detect the presence of the substrate 150₂ when the beam is interrupted or attenuated. For example, the one or more sensors 211 are positioned to view an area above the substrate 150₂. When an edge or center of the substrate 150₂ bows, the beam is attenuated. Thus, the one or more sensors 211 detect the movement of the substrate 150₂, at least in the Z direction, which indicates bowing of the substrate 150₂.

In this example, the information received from the sensors 211 may be monitored and, in one embodiment, utilized to correct the orientation of the showerhead assembly 160C relative to the substrate 150₂. In another embodiment, the distance D₁ of the showerhead assembly 160C relative to the substrate 150₂ may be controlled to produce a non-parallel relationship between the substrate 150₂ and a lower surface of the showerhead assembly 160C. In this embodiment, deposition uniformity may be tuned or changed by varying the spacing between the lower surface of the showerhead assembly 160C and the substrate 150₂.

In yet another embodiment, the distance D₁ of the showerhead assembly 160C relative to the substrate 150₂ may not be dependent on the planarity of the substrate 150₂ or the substrate receiving surface 205. For example, the spacing of the showerhead assembly 160C may be controlled to provide a distance D₂ between a lower surface of the showerhead assembly 160C and an electrode, such as a shunt electrode 180. In this embodiment, the distance D₂ may be controlled to produce a parallel or, alternatively, a slightly non-parallel relationship between the shunt electrode 180 and the lower surface of the showerhead assembly 160C. In this embodiment, deposition uniformity on the substrate 150₂ may be tuned or changed by varying the spacing between the lower surface of the showerhead assembly 160C and the shunt electrode 180.

The showerhead assembly 160C is coupled to the primary gas source 128, the secondary gas source 129 and the power source 130 by dedicated conduits 125A, 126A and 127A, respectively. Each of the conduits 125A, 126A and 127A may be tubes, hoses, bellows, wires or cables having suitable valving and/or control circuits adapted to contain fluids or provide electrical communication. In one embodiment, each of the conduits 125A, 126A and 127A include a flexible portion 210A, 210B and 210C which allows communication with the gas sources 128 and 129, and power source 130 during movement of the showerhead assembly 160C. Each of the flexible portions 210A, 210B may be hoses, bellows or flexible tubes that are adapted to contain gases while allowing movement of the showerhead assembly 160C. The flexible portion 210C of the conduit 127A may be a cord or a flexible cable. Thus, the showerhead assembly 160C is able to move relative to the substrate receiving surface 205, the substrate 150₂ and/or the shunt electrode 180 in at least two distinct and orthogonal directions while maintaining communication between the sources 128, 129 and 130.

In this embodiment, the showerhead assembly 160C is coupled to a remote plasma source 240 adapted to flow a plasma of reactive species to the showerhead assembly 160C. The remote plasma source 240 may be used to deliver a plasma that is utilized in a deposition process and/or a cleaning process. The remote plasma source 240 includes a chamber (not shown) that is adapted to receive gases from one or both of the primary gas source 128 and the secondary gas source 129. Alternatively or additionally, the remote plasma source 240 may be coupled to a dedicated cleaning gas source 242. Examples of cleaning gases include fluorine (F₂), nitrogen trifluoride (NF₃), sulfur hexafluoride (SF₆) and carbon/fluorine containing gases, such as fluorocarbons, for example octofluorotetrahydrofuran (C₄F₈O), carbonyl fluoride (COF₂), hexafluoroethane (C₂F₆), tetrafluoromethane (CFO, perfluoropropane (C₃F₈), and combinations thereof.

The remote plasma source 240 may be configured as an inductively or capacitively coupled reactor, or include a microwave generator adapted to excite a gas from one or both of the primary gas source 128, the secondary gas source 129 and/or the cleaning gas source 242. In one embodiment, the activated gas is coupled to and flows to the showerhead assembly 160C through the conduit 125A and flexible portion 210B. While not shown, a single remote plasma source 240 as described herein may be coupled to all of the showerhead assemblies of FIG. 1. Alternatively, each of the showerhead assemblies 160A-160C of FIG. 1 may be coupled to a dedicated remote plasma source 240 as described herein.

FIG. 3A is a schematic side cross-sectional view of one embodiment of a showerhead assembly 360 that may be utilized as one or more of the showerhead assemblies 160A-160C in FIG. 1. In one embodiment, the showerhead assembly 360 includes a body 172 having at least two distinct gas delivery channels formed therein, which include an outer gas channel, or first gas channel 174A, and an inner gas channel, or second gas channel 174B. In general, each of the first gas channel 174A and second gas channel 174B are utilized to deliver one or more gases to a surface of a substrate 150₂ disposed in the internal volume 115. At least a portion of the lower surface of the first and second gas channels 174A, 174B include a plurality or holes, slots, or ports formed therein.

In one embodiment, the first gas channel 174A is adapted to deliver a processing gas (e.g., flow path F′) to a surface 306 of the substrate 150₂ and the second gas channel 174B is adapted to deliver a second type of gas (e.g., flow path F″) to the surface 306 of the substrate 150₂. In one embodiment, the second gas channel 174B is configured to deliver an inert or non-reactive gas which surrounds and encloses a processing gas delivered through the first gas channel 174A (e.g., flow path F′).

In this configuration, the gas delivered from the second gas channel 174B thus tends to act as a “gas curtain,” which encloses a localized showerhead processing region 309, and limits the lateral (X and/or Y direction) diffusion of the processing gas from the formed showerhead processing region 309. Therefore, by enclosing the reactive components in the processing gases within the showerhead processing region 309, the majority of the reactive components will interact and deposit on the substrate surface 306. The showerhead processing region 309 also minimizes the unwanted deposition on the various processing chamber 100 components. The showerhead processing region 309 also prevents cross contamination between the deposition processes separately performed by each of the showerhead assemblies 160A-160C (FIG. 1).

For instance, the showerhead processing region 309 is desirable and provides for the concentration of the reactive components disposed within the showerhead processing region 309 to be high, while the concentration of reactive components in the regions outside of the showerhead processing region 309, or the internal volume 115, to be low. It is believed that by controlling one or a combination of the temperature of the substrate 150₂, the energy of the reactive species contained in the various gases, and the flow rate of the gases delivered to the surface of the substrate 150₂, the efficiency with which the delivered reactive species are incorporated in the deposited film versus being lost into the internal volume 115 can be controlled. Therefore, rather than filling the entire internal volume 115 with the processing gas during a deposition process, which is common in conventional chemical vapor deposition processes, the novel showerhead assemblies 160A-160C and methods described herein minimize the amount of wasted processing gas that does not directly interact with the substrate surface. One will note that the required temperature of the substrate, energy of the reactive species, and the flow rates of the gases to achieve a desired deposition efficiency will generally vary depending on the types of reactive species contained in the processing gas, the desired deposition rate, the initial temperature of the substrate, and the processing pressure in the internal volume 115.

FIG. 3B is a bottom view of the showerhead assembly 360 illustrated in FIG. 3A that has been rotated 90 degrees about the Z direction. The showerhead assembly 360 generally includes the first gas channel 174A that is surrounded by a plurality of sidewalls 260A, 260B. The first gas channel 174A also includes a lower surface or first output face 270A having openings or perforations 250A, such as holes or slots formed therein, to direct a gas towards the substrate 150₂. The second gas channel 174A is formed between the interior sidewalls 260A also includes a lower surface or second output face 270B that has a plurality of openings or perforations 250B formed therein to direct a gas towards the substrate 150₂. In one embodiment, the output faces 270A and 270B are coplanar.

FIG. 3B also schematically illustrates the orientation of a portion of the substrate 150₂, relative to the showerhead assembly 360. In this embodiment, the length of the showerhead assembly 360 is greater than a width W of the substrate 150₂ by a length L at each end 207A, 207B of the showerhead assembly 360. The extra length L minimizes or eliminates any edge effects or deposition non-uniformity at the edges of the substrate 150₂. Thus, the length L at each end 207A, 207B provides greater deposition uniformity across the width W of the substrate 150₂. In one embodiment, the length L is equal to about 1.0 inches to about 2.5 inches greater than the width W of the substrate 150₂. In another embodiment, the length L is greater than or equal to about 6% to about 12.5% of the width W of the substrate 150₂.

The secondary gas source 129 may be adapted to deliver inert gases, non-reactive gases, reactive gases and combinations thereof. In one embodiment, the secondary gas source 129 is adapted to deliver a non-reactive or inert gas that is used as a purge gas, a cooling gas and/or a carrier gas. Examples of purge, cooling or carrier gases that may be provided by the secondary gas source 129 include, but are not limited to argon (Ar), helium (He), nitrogen (N₂), oxygen (O₂), hydrogen (H₂), nitrogen dioxide (NO₂), nitrous oxide (N₂O), and ammonia (NH₃). In another embodiment, the secondary gas source 129 includes reactive gases that may be used to clean components disposed in the internal volume 115. The power source 130 is adapted to provide radio frequency (RF) power, alternating current (AC) power or direct current (DC) power.

In one embodiment of the processing chamber 100, a pumping device 142 is coupled to the internal volume 115 to evacuate and control the pressure therein via a throttle valve 116. The pumping device 142 may be a conventional rough pump, roots blower, turbo pump or other similar device that is adapted control the pressure in the internal volume 115. In one embodiment, the pressure level of the internal volume 115 of the processing chamber 100 may be maintained at less than about 760 Torr. In one embodiment, the pressure level of the interior volume 115 of the processing chamber 100 may be maintained at about 1 Torr or less. In another embodiment, the pressure level within the processing chamber 100 may be maintained at about 10⁻³ Torr or less. In yet another embodiment, the pressure level within the processing chamber 100 may be maintained at about 10⁻³ Torr to about 10⁻⁷ Torr.

During processing of the substrate 150₂, it is sometimes beneficial to determine properties of the substrate 150₂ and/or properties of thin films that are deposited on the substrate 150₂. The properties include film thickness, stress, surface roughness and/or density. The metric may be obtained ex-situ (outside the chamber) or in-situ (inside the chamber). In one embodiment, the property metric may be determined in-situ by at least one inspection device 190 coupled to the processing chamber 100 in a position to view the substrate 150₂. The at least one inspection device 190 is adapted to view and/or scan the entire width of the substrate 150₂ (in the Y direction). In this embodiment, the at least one inspection device 190 is a plurality of inspection devices arranged in a substantially linear arrangement in the Y directional plane. For example, the at least one inspection device 190 may utilize a plurality of inspection devices that are adapted to impinge the upper surface of the substrate 150₂ in a scan area 192 that is substantially linear in the Y direction along the width of the substrate 150₂. In one embodiment, the at least one inspection device 190 is an electromagnetic energy emitter adapted to analyze a property of a substrate 150₂ using an x-ray diffraction (XRD) technique, an x-ray photoelectron spectroscopy (XPS) technique, a reflectometry technique or an ellipsometry technique.

In one embodiment, as illustrated in FIG. 3A, the showerhead assembly 360 is further configured to form a plasma 305 above the upper surface 306 of the substrate 150₂ to increase the energy of the reactive species in the processing gas. As shown, the showerhead assembly 360 is coupled to the primary gas source 128, secondary gas source 129 and power source 130 by conduits 210A, 210B and 210C. In this embodiment, a process gas is delivered to the second gas channel 174B of the showerhead assembly 360 from the primary gas source 128. The process gas is caused to flow through the perforations 250B along a first flow path F′ toward the substrate 150₂. Power is applied to the showerhead assembly 360 from the power source 130 to form a plasma 305 between the output face 270B of the showerhead assembly 360 and the upper surface 306 of the substrate 150₂. In this embodiment, the power source 130 is a RF generator and is coupled to a matching circuit 315 to tune the power application and the plasma 305. Additionally, a purge gas is delivered to the first gas channel 174A of the showerhead assembly 360 from the secondary gas source 129. A shunt electrode 180 may be utilized in this embodiment to control and facilitate the formation of the plasma 305. In one embodiment, the shunt electrode 180 is coupled to a configurable ground 383 that selectively alters the ground potential of the shunt electrode 180.

In one embodiment, the secondary gas from the secondary gas source 129 flows through the perforations 250A along a second flow path F″ towards the substrate 150₂. The second flow path F″ is caused to flow at a pre-determined flow rate and velocity to create a gas curtain that defines the showerhead processing region 309 that is separated from the internal volume 115 within an internal zone 308. The process gas from the primary gas source 128 flows though the perforations 250B along the first flow path F′ within the showerhead processing region 309 and any non-dissociated process gases are substantially contained in the internal zone 308. The plasma 305 is formed above the substrate 150₂ to apply a thin film to the upper surface 306 of the substrate 150₂ while the substrate 150₂ is moving or stationary relative to the showerhead assembly 360. In this embodiment, the volume of process gases may be minimized due to the reduced volume defined by the internal zone 308 interior of the gas curtain.

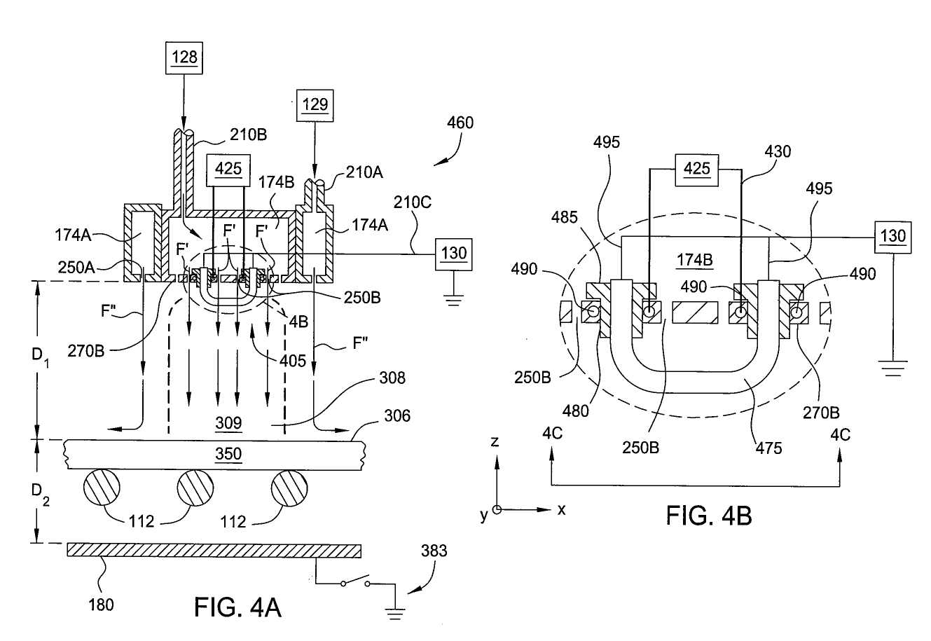

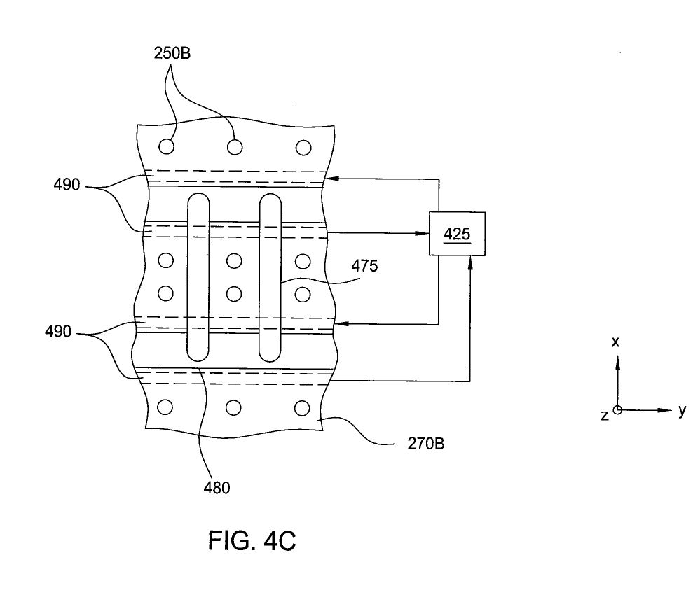

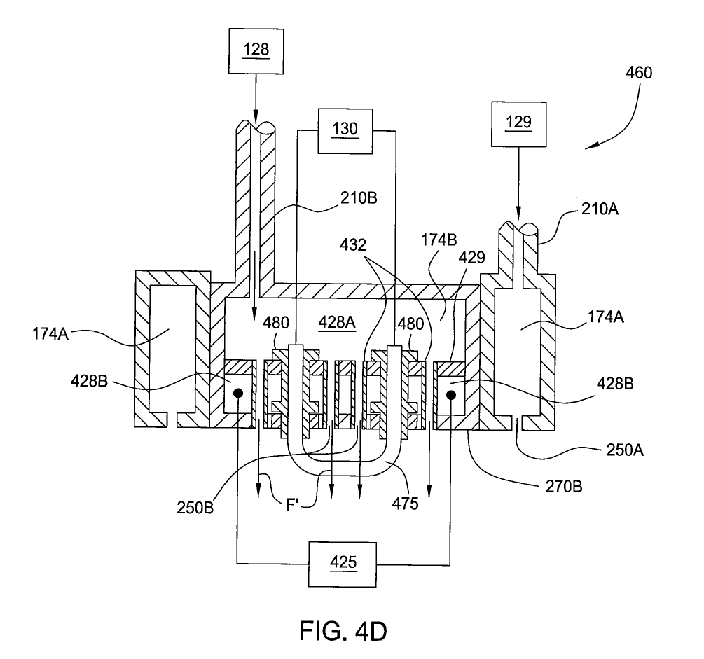

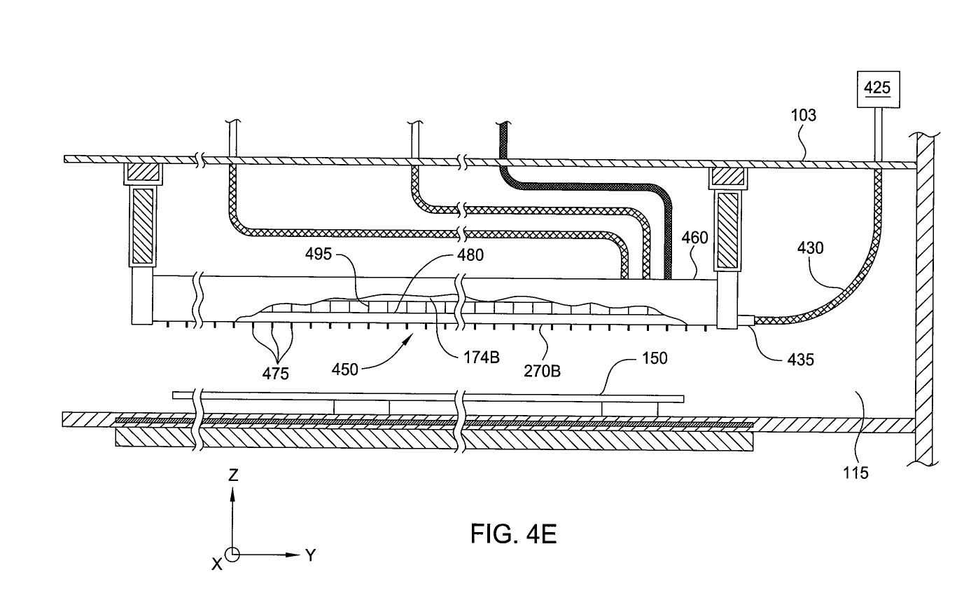

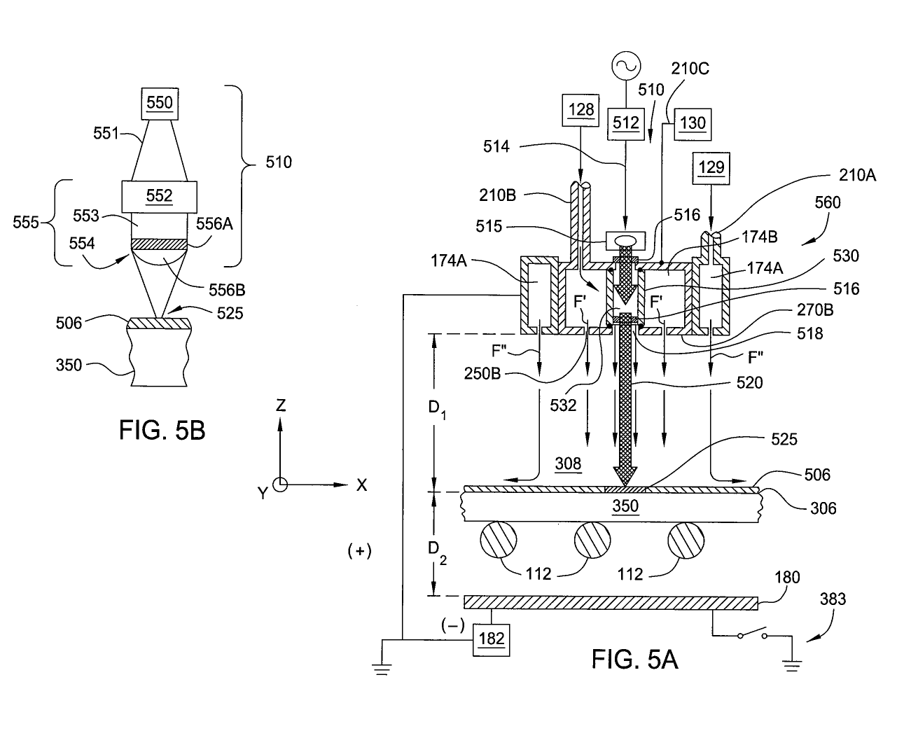

In one embodiment, as shown in FIG. 3B, the second gas channel 174B includes a longitudinal zone 255 (bounded by dashed lines) that may be similar or different than the remainder of the second gas channel 174B. In one aspect, the longitudinal zone 255 of the showerhead assembly 360 is configurable to vary the type of processes performed by the showerhead assembly 360. For example, the longitudinal zone 255 may be configured for different deposition, cleaning, or thermal apparatus. In one embodiment, the longitudinal zone 255 includes perforations 250B and/or provides a support surface for other apparatus. In another embodiment, the longitudinal zone 255 may be a void adapted to receive an energy emitting apparatus, such as a radiant heat source, an electromagnetic energy emitter or a light source. The longitudinal zone 255 may also include hardware associated with the energy emitting apparatus. Various embodiments of the showerhead assemblies 160A, 160B and 160C of FIG. 1 for different processes are described in more detail in FIGS. 4A-5B.

FIG. 4A is a schematic side cross-sectional view of another embodiment of a showerhead assembly 460 which may be utilized as any one or all of the showerhead assemblies 160A, 160B and 160C shown in FIG. 1. In this embodiment, the showerhead assembly 460 is includes a heating element 405 adapted to perform a chemical vapor deposition (CVD) process, such as hot wire CVD (HWCVD) or catalytic CVD (Cat-CVD) process. In this embodiment, the substrate 350 is similar to the substrate 150₂ as described in FIGS. 1-3B. The showerhead assembly 460 is coupled to the primary gas source 128, secondary gas source 129 and power source 130 by conduits 210A, 210B and 210C as described in FIG. 3A.

FIG. 4B is an exploded cross-sectional view of a portion of the showerhead assembly 460 of FIG. 4A. The heating element 405 includes a filament 475 disposed between one or more insulating members 480 that are coupled to the showerhead assembly 460. The filament 475 is in the form of a wire or cylinder that is coupled to the power source 130 by one or more electrical leads 495. In this embodiment, the power source 130 is configured as an AC or DC power supply to deliver an electrical current to heat the filament 475 to temperatures exceeding 1500° C. during processing. The filament 475 may be made of a refractory material or other material having the ability to retain physical and chemical properties when subjected to the high processing temperatures. Examples of materials for the filament 475 include tungsten (W) or tantalum (Ta), or alloys thereof.

In this embodiment, the filament 475 is shown in side view in the shape of a “U” but the filament 475 may be in other shapes. Additionally, the filament 475 shown is one of many heating elements coupled to the showerhead assembly 460 along the Y directional axis of the showerhead assembly 460. Thus, the showerhead assembly 460 includes a plurality of filaments 475 as shown in FIG. 4C. In one embodiment, the filaments are positioned in an array or other desirable pattern across a surface of the showerhead assembly 460.

In one embodiment, the showerhead assembly 460 is adapted to deposit thin silicon films in a widely varying order and crystallinity or structure. Silanes may be provided from the primary gas source 128 to the second gas channel 174B and caused to flow through the perforations 250B along the first flow path F′ toward the substrate 350. Power is applied to the filament 475 from the power source 130 to form atomic radicals between the output face 270B and an upper surface 306 of the substrate 350. Additionally, a purge gas is delivered to the first gas channel 174A of the showerhead assembly 360 from the secondary gas source 129 to enclose the reactive gas components within the showerhead processing region 309.

In this embodiment, the secondary gas from the secondary gas source 129 flows through the perforations 250A along the second flow path F″ to create a gas curtain that defines a showerhead processing region 309 that is separated from the internal volume 115. The process gas from the primary gas source 128 flows though the perforations 250B along the first flow path F′ within the showerhead processing region 309 and the radicals and any non-dissociated process gases are substantially contained in the internal zone 308 bounded by the gas curtain and the substrate 350. In this embodiment, the volume of process gases may be minimized due to the reduced volume defined by the showerhead processing region 309 interior of the gas curtain. The radicals are deposited on the substrate 350 to form a thin film on the upper surface 306 of the substrate 350 while the substrate 350 is moving or stationary relative to the showerhead assembly 460. Additionally or alternatively, the showerhead assembly 460 may move in the X direction with the substrate 350, or relative to the substrate 350 in the X or Z direction regardless of any movement of the substrate 350.

The insulating members 480 provide a coupling point for mounting the filament 475 to the showerhead assembly 460 and insulate the showerhead assembly 460 electrically and thermally from the filament 475. The insulating members 480 may be made of an insulating material, such as ceramics, alumina, zirconia, or other similar material. In one embodiment, portions of the showerhead assembly 460 are coupled to a coolant source 425 that is in communication with coolant channels 490 formed in or on a surface of one of the walls of the showerhead assembly 460. A conduit 430 is coupled to the coolant channels 490 to provide a coolant, such as nitrogen gas (N₂) ethylene glycol, deionized water, or other suitable coolant, from the coolant source 425.

FIG. 4C is a schematic bottom view of the showerhead assembly 460 taken along lines 4C-4C of FIG. 4B showing one embodiment of a coolant line configuration. In this embodiment, one or more coolant channels 490 (shown in phantom) are formed in or on a surface the showerhead assembly 460. Cooling fluid from the coolant source 425 is circulated through each of the coolant channels 490 to dissipate heat from the filaments 475 and/or the showerhead assembly 460.

FIG. 4D is a schematic cross-sectional view of another embodiment of a showerhead assembly 460. In this embodiment, an alternative coolant line configuration is shown. In this embodiment, the second gas channel 174B has been modified to include a gas feed channel 428A and a coolant circulation channel 428B. The coolant circulation channel 428B is isolated from the gas feed channel 428A in order to flow a coolant therein. Likewise, the gas feed channel 428A includes a plurality of tubular members 432 to isolate the gas feed channel 428A from the coolant circulation channel 428B. In one embodiment, each of the tubular members 432 are extensions of the perforations 250B allowing a gas from the primary gas source 128 to flow from the gas feed channel 428A to form the first flow path F′. Each of the tubular members 432 are sealed between an intermediate perforated plate 429 and the output face 270B to contain fluid within the coolant circulation channel 428B and isolate gas from the coolant circulation channel 428B. In one embodiment, each of the tubular members 432 may be made of the same material as the showerhead assembly 460 and welded, brazed or otherwise coupled to each of the intermediate perforated plate 429 and the output face 270B.

FIG. 4E is a side view of the showerhead assembly 460 shown in FIGS. 4A and 4B showing one embodiment of an insulating member 480. In this Figure, a portion of the body of the showerhead assembly 460 is cut-away to show a portion of the second gas channel 174B. Also, in this Figure, a plurality of filaments 475 are shown in an exemplary pitch across the length of the showerhead assembly 460 to form an array 450 of heating elements. Each of the plurality of filaments 475 may be coupled together or in groups by the electrical leads 495 to the power source 130 to function in series or in discrete zones. In this embodiment, the plurality of filaments 475 are coupled to the insulating member 480, which is in the form of a bar that spans the length of the showerhead assembly 460. A coupling device 435 is disposed on one end of the showerhead assembly 460 that engages the conduit 430 and couples the coolant channels 490 to the coolant source 425. In this embodiment, the showerhead assembly 460 is adapted to move in at least a vertical (Z) direction and the conduit 430 is configured as a flexible tube or hose to allow the showerhead assembly 460 to be in communication with the coolant source 425 during any movement of the showerhead assembly 460.

FIG. 5A is a schematic side cross-sectional view of another embodiment of a showerhead assembly 560 which may be utilized as any one or all of the showerhead assemblies 160A, 160B and 160C shown in FIG. 1. In this embodiment, the showerhead assembly 560 includes an energy emitting device 510 that directs and delivers energy to the surface 306 of the substrate 350. In this embodiment, the showerhead assembly 560 is adapted to enable a deposition process, an annealing process, a repair process, a cleaning process, an ablation process, or combinations thereof, on the surface 306 of the substrate 350. The energy emitting device 510 may include, but is not limited to, an optical radiation source, e.g. laser, an electron beam source, an ion beam source, or a microwave energy source. In this embodiment, the substrate 350 is similar to the substrate 150₂ as described in FIGS. 1-3B.

In one embodiment, the energy emitting device 510 is an optical radiation source which includes a laser source 512 adapted to emit continuous or intermittent electromagnetic radiation. In one embodiment, the electromagnetic radiation emitted by the laser source 512 has a wavelength between about 600 nm and about 1000 nm that impinges a thin film layer 506 on the surface 306 of the substrate 350. In another embodiment, the electromagnetic radiation emitted by the laser source 512 has a wavelength between about 808 nm and about 810 nm. In one aspect, the extinction coefficient of the thin film layer 506 at a wavelength of about 808 nm to about 810 nm is about 0.01 to about 2.0. Typically, the power density of the electromagnetic radiation emitted by the laser source 512 is between about 10 kW/cm² and about 200 kW/cm², such as about 90 kW/cm². In one embodiment, the laser source 512 is adapted to deliver continuous or pulsed energy at a wavelength of 532 nm, 748 nm or 1064 nm. In one embodiment, the laser source 512 may project pulsed energy with pulse length of between about 8 ns to about 30 ns. In another embodiment, the pulse length of the laser source 512 may be about 20 ns.

In one embodiment, the laser source 512 emits a continuous or intermittent primary beam 514 that is directed towards beam shaping optics 515 to form a secondary beam 520 that is directed to impinge the upper surface 306 of the substrate 350. The secondary beam 520 may pass through one or more windows 516 prior to impinging the substrate 350. The one or more windows 516 may be made of quartz or sapphire and adapted to be at least partially transparent to the wavelengths emitted by the laser source 512. Additionally or alternatively, the one or more windows 516 may be filters and/or utilized as additional light shaping optics.

In one embodiment, the secondary beam 520 is directed through the second gas channel 174B and is separated from the volume of the second gas channel 174B by a sleeve or walls 530. The walls 530 form a light pipe or tunnel 532 that effectively isolates the secondary beam 520 from the volume of the second gas channel 174B. The walls 530 may be made of an opaque material that is also electrically and thermally insulative. The walls 530 may be integral parts of the showerhead assembly 560 or be formed in discrete sections. The walls 530 may be coupled to the interior surface of the interior gas channel 174B by seals to prevent gases from entering the tunnel 532.

In this embodiment, the secondary beam 520 forms a strike zone 525 on the substrate 350 that heats at least the upper surface 306 of the substrate 350. The strike zone 525 as shown in FIG. 5A may be a cross-section of a discrete spot from a single laser source 512 or a cross-section of a line formed from one or more laser sources 512 (not shown in this view) that extend in the Y direction along the length of the showerhead assembly 560. For example, in one embodiment, the showerhead assembly 560 may include only a single laser source 512 that is configured to emit a secondary beam 520 across the width of the substrate 350. One or a combination of the laser source 512, the beam shaping optics 515 and windows 516 may be configured to shape the secondary beam 520 into a substantially unbroken line. In another example, multiple laser sources 512 that are aligned linearly in the Y-direction may be utilized to form a secondary beam 520 in a line across the upper surface 306 of the substrate 350. In another example, multiple laser sources 512 may be staggered along the Y direction in a zig-zag or saw-tooth pattern to form the secondary beam 520 in a substantially straight line across the upper surface 306 of the substrate 350.

As described above, the strike zone 525 may be a cross-section of a discrete spot or a cross-section of a line. In the case of a spot, which may be rectangular, circular or oval depending on the configuration of the beam shaping optics 515, the strike zone 525 includes at least one periphery to periphery dimension of about 10 mm to about 26 mm. In the case of a rectangular shaped spot, the size of the spot may be between about 10 mm by about 10 mm to about 26 mm by about 26 mm. In the case where the strike zone 525 is a cross-section of a line, the cross-sectional dimension would be between about 10 mm to about 26 mm. In one embodiment, the laser source 512 may project pulsed energy by the secondary beam 520 to the strike zone 525 at density of about 0.5 Joules/cm² to about 1.5 Joules/cm².

In one embodiment, the showerhead assembly 560 is adapted for a deposition process, such as laser-induced chemical vapor deposition (LCVD) process. The LCVD processes as described herein may be used alone or in combination with a deposition process to form thin films, an ablation process, a repair process, or a combination of ablation followed by a repair process using LCVD deposition or other deposition process. The substrate 350 may be moved relative to the showerhead assembly 560 or stationary relative to the showerhead assembly 560. Additionally or alternatively, the showerhead assembly 560 may move in the X direction with the substrate 350, or relative to the substrate 350 in the X or Z direction regardless of any movement of the substrate 350.

Process gas may be provided intermittently or continuously during activation of the laser source 512 depending on process requirements. For example, the laser source 512 may be activated without the presence of process gases to heat the substrate 350. The secondary gas from the secondary gas source 129 may be flowed to create a gas curtain that defines an internal zone 308 that is separated from the internal volume 115. Thus, an area of the substrate 350 corresponding to the strike zone 525 may be heated and/or ablated by the secondary beam 520 and any by-products may be contained in the internal zone 308 and subsequently flowed away from the substrate 350. Thereafter, if desired, a process gas is flowed from the primary gas source 128 to the second gas channel 1748 along the first flow path F′ towards the substrate 350. Power is applied to the laser source 512 to form the strike zone 525 on the upper surface 306 of the substrate 350 to deposit materials thereon.

Generally, in a LCVD deposition process, a process gas is delivered from the primary gas source 128 to the second gas channel 174B along the first flow path F′ towards the substrate 350. The secondary gas from the secondary gas source 129 may be delivered to form the internal zone 308 that is separated from the internal volume 115. The dissociation of the precursors from the primary gas source 128 that are present in the internal zone 308 may be activated thermally (pyrolytic LCVD) non-thermally (photolytic LCVD) or a combination thereof (photophysical LCVD).

In a pyrolytic LCVD process, the secondary beam 520 irradiates the strike zone 525 and heats the strike zone 525 locally. The precursors impinge the heated region at the strike zone 525 and undergo thermal decomposition. In a photolytic LCVD process, the gas phase precursors and/or the surface adsorbed precursors are dissociated by the energy of the secondary beam 520 and/or the energy at the strike zone 525. In a photophysical LCVD process, the precursors from the primary gas source 128 are activated by a combination photochemical dissociation and thermal decomposition. In any of the LCVD processes, precursors present on the process gas are activated and are deposited on the substrate 350 to form a thin film while the substrate 350 is moving or stationary relative to the showerhead assembly 560. In this embodiment, the volume of process gases may be minimized due to the reduced volume in the internal zone 308 defined within the gas curtain.

In one embodiment, deposition on the substrate 350 may be assisted by RF power application. In this embodiment, the energy of the secondary beam 520 is at a wavelength that ionizes the precursors from the primary gas source 128. In one embodiment, RF energy may be applied between the shunt electrode 180 and the showerhead assembly 560 to assist in plasma formation and/or maintenance between the output face 270B of the showerhead assembly 560 and an upper surface 306 of the substrate 350. In one specific embodiment, RF energy may be supplied from a power source 182 coupled to the shunt electrode 180. In this embodiment, the shunt electrode 180 is biased negatively (−) and the showerhead assembly 560 is biased positively (+). In another embodiment, the power source 130 may be adapted to supply RF power to the showerhead assembly 560 in addition to supplying AC or DC power. In this embodiment, the shunt electrode 180 may function as a ground plane to assist in plasma formation and/or maintenance between the output face 270B of the showerhead assembly 560 and an upper surface 306 of the substrate 350. In either embodiment, the shunt electrode 180 may be coupled to a configurable ground 383.

FIG. 5B is a schematic side view of one embodiment of an energy emitting device 510 of FIG. 5A that may be utilized in an annealing process. The energy emitting device 510 includes a continuous wave electromagnetic radiation source 550 and focusing optics 555. The focusing optics 555 includes a collimator assembly 552 having one or more collimators to collimate radiation 551 from the continuous wave electromagnetic radiation source 550 into a substantially parallel beam of collimated radiation 553. The collimated radiation 553 is then focused by a lens assembly 554 which includes at least one lens 556A, 556B. The lens assembly 554 focuses the collimated radiation 553 into the secondary beam 520 of radiation focused at the thin film layer 506.

Lenses 556A, 556B may be any suitable lens, or series of lenses, capable of focusing radiation into a linear beam. In one embodiment, lens 556A is a cylindrical lens. Alternatively, lens 556A may be one or more concave lenses, convex lenses, plane mirrors, concave mirrors, convex mirrors, refractive lenses, diffractive lenses, Fresnel lenses, gradient index lenses, or the like. In one embodiment, the continuous wave electromagnetic radiation source 550 comprises multiple laser diodes, each of which produces uniform and spatially coherent light at the same wavelength. In this embodiment, the power of the laser diodes is in the range of 0.5 kW to 50 kW, for example, approximately 2 kW. Suitable laser diodes are made by Coherent Inc. of Santa Clara, Calif.; Spectra-Physics of California; or by Cutting Edge Optronics, Inc. of St. Charles Mo.

In an annealing process, the strike zone 525 from the secondary beam 520 is used to elevate the temperature of the thin film layer 506 at regions where the strike zone 525 impinges. In this embodiment, the secondary beam 520 is used to heat regions of the thin film layer 506 to a desired temperature and then the secondary beam 520 is deactivated to allow the heated regions to cool. In one embodiment, the substrate 350 may be moved relative to the showerhead assembly 560 and strike zone 525. Additionally or alternatively, the showerhead assembly 560 may move in the X direction with the substrate 350, or relative to the substrate 350 in the X or Z direction regardless of any movement of the substrate 350. In one embodiment, the secondary beam 520 is pulsed to form intermittent strike zones 525 on the substrate 350. In another embodiment, the secondary beam 520 is constant while the substrate 350 is moved allowing the strike zone 525 to impinge different portions of the upper surface 306 of the substrate 350. In one embodiment, a thin film layer 506 is heated to a temperature between about 1100° C. and about 1410° C., and cooled down to near ambient temperature in a time period on the order of 1 millisecond.

In one embodiment, the electromagnetic radiation emitted by the electromagnetic radiation source 550 has a wavelength between about 808 nm and about 810 nm. In this embodiment, the extinction coefficient of the thin film layer 506 at a wavelength of about 808 nm to about 810 nm is about 0.01 to about 2.0. Typically, the power density of the electromagnetic radiation emitted by the electromagnetic radiation source 550 is between about 10 kW/cm² and about 200 kW/cm², such as about 90 kW/cm². In one embodiment, the electromagnetic radiation source 550 may project pulsed energy with pulse length of between about 8 ns to about 30 ns. In another embodiment, the pulse length of the electromagnetic radiation source 550 may be about 20 ns. In another embodiment, the electromagnetic radiation source 550 is capable of emitting radiation continuously for at least 15 seconds.

In one embodiment of laser annealing, the substrate 350 is scanned with a line of radiation emitted by the secondary beam 520. The line of electromagnetic radiation may be between about 3 μm and about 500 μm in width, such as about 35 μm wide. The electromagnetic radiation emitted by the secondary beam 520 is substantially absorbed by the thin film layer 506. The thin film layer 506 reflects little if any of the electromagnetic radiation emitted by the laser source 512. Thus, the thin film layer 506 may be described as both an absorber layer and an anti-reflective coating layer. The thin film layer 506 then transfers the thermal energy created by the absorbed electromagnetic radiation to the substrate 350, and the substrate 350 is heated and annealed. In one embodiment, only the upper portion of the substrate 350 is heated, such as to a depth of about 15 μm of the substrate surface that faces the secondary beam 520. Thus, in one embodiment, the annealing process is a dynamic surface annealing (DSA) process.

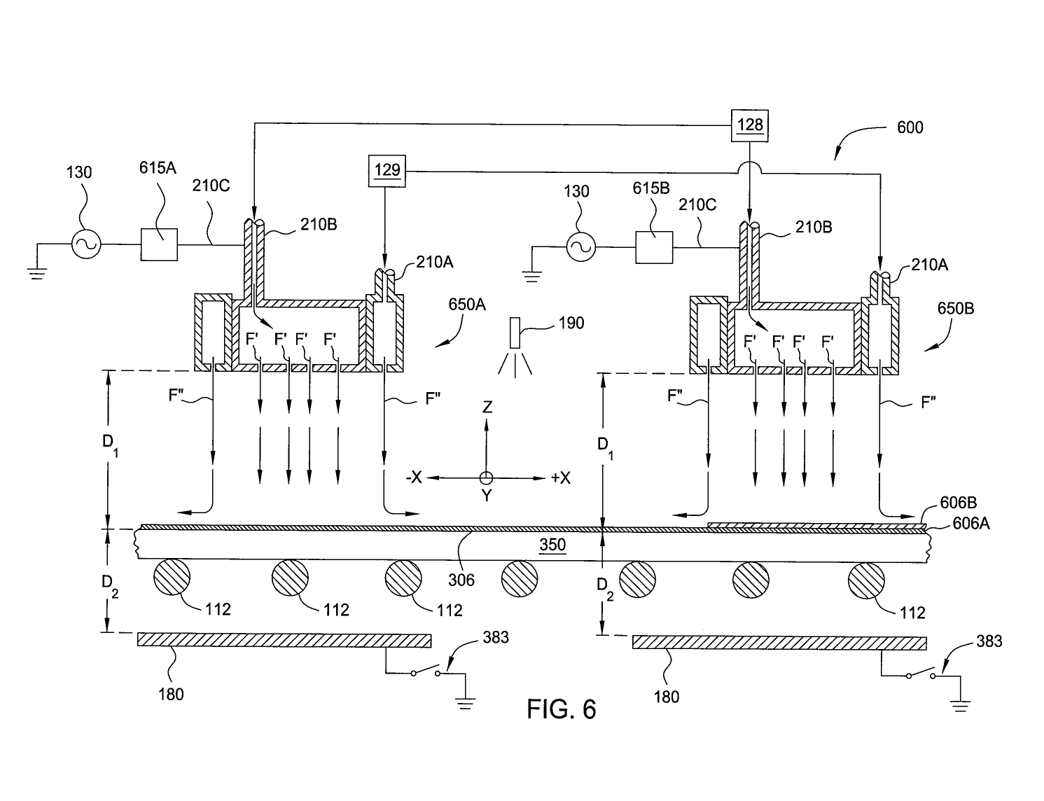

FIG. 6 is a schematic side cross-sectional view of one embodiment of a pass-by substrate processing apparatus 600 that may be utilized in the processing chamber 100 of FIG. 1. In this embodiment, the substrate processing apparatus 600 utilizes two showerhead assemblies 650A and 650B that may be configured as one or a combination of the showerhead assemblies described in FIGS. 3A-5. For example, one or both of the showerhead assemblies 650A and 650B may be configured for a deposition process, an annealing process, a repair process, or combinations thereof. While not shown, additional showerhead assemblies may be used in connection with the showerhead assemblies 650A and 650B. The additional showerhead assemblies may be configured for a deposition process, an annealing process, a repair process, or combinations thereof. In this embodiment, the substrate 350 is similar to the substrate 150₂ as described in FIGS. 1-3B.

In this embodiment, each of the showerhead assemblies 650A and 650B are configured for a deposition process using RF plasma. While not shown, one or more of the showerhead assemblies 650A and 650B may be configured for a HWCVD process (FIGS. 4A-4E) or include an energy emitting device 510 (FIGS. 5A-5B) configured for an LCVD process, an annealing process, an ablation process, a repair process, or combinations thereof. However, in this example, each of the showerhead assemblies 650A and 650B are configured to deposit a thin film on the upper surface 306 of the substrate 350 using a PECVD process.

In one specific embodiment, the showerhead assemblies 650A and 650B are coupled to the power source 130 and are configured as a RF electrode. In this embodiment, each of the showerhead assemblies 650A and 650B are coupled to separate matching circuits 615A, 615B, respectively. In one example, the showerhead assembly 650A forms a plasma to deposit the first thin film 606A and the showerhead assembly 650B forms a plasma to deposit the second thin film 606B. The process recipe for the second thin film 606B may be determined by the metric obtained from an inspection device 190 disposed in the internal volume 115. In one embodiment, the thin films are deposited sequentially while the substrate 350 is moved intermittently or continuously in the −X direction relative to the showerhead assemblies 650A and 650B. In an additional or alternative embodiment, one or both of the showerhead assemblies 650A and 650B may move in the X direction with the substrate 350, or relative to the substrate 350 in the X or Z direction regardless of any movement of the substrate 350.

In one aspect, the showerhead assembly 650A deposits a first thin film 606A on the upper surface 306 while the showerhead assembly 650B deposits a second thin film 606B on the first thin film 606A. In this embodiment, the showerhead assembly 650A and the showerhead assembly 650B may be utilized to form sequential layers on the upper surface 306 of the substrate 350. In one aspect, the first thin film 606A and the second thin film 606B include distinct properties, such as crystalline structure, uniformity, thickness, density, composition and electrical properties. In one embodiment, the showerhead assemblies 650A and 650B may be utilized to alter the properties of one or both of the first thin-film 606A and second thin film 606B. In one embodiment, the showerhead assembly 650A deposits the first thin film 606A with a first property and the showerhead assembly 650B deposits and/or alters the second thin film 606B to have a second property that is different than the first property as the substrate 350 is moved. The inspection device 190 may be utilized to obtain a metric of the first thin film 606A properties as the substrate 350 moves through the system.

In another embodiment (not shown), the showerhead assembly 650B may be configured to alter the first thin film 606A deposited by the showerhead assembly 650A. The alteration of the first thin film 606A may include repair of portions of the first thin film 606A, annealing of the first thin film 606A, and combinations thereof. In this embodiment, the showerhead assembly 650B may be equipped with an energy emitting device 510 (FIGS. 5A, 5B) to perform an ablation process, a LCVD repair, an annealing process, a deposition process, and combinations thereof. The ablation, repair and/or annealing process may be determined based on a metric of the first thin film 606A obtained from the inspection device 190. After alteration of the first thin film 606A and/or deposition of the second thin film 606B, a third showerhead assembly (not shown) may be utilized to deposit a third thin film (not shown) over the first thin film 606A and/or second thin film 606B. Alternatively, the third showerhead assembly may be configured to alter one or both of the first and second thin films 606A, 606B.

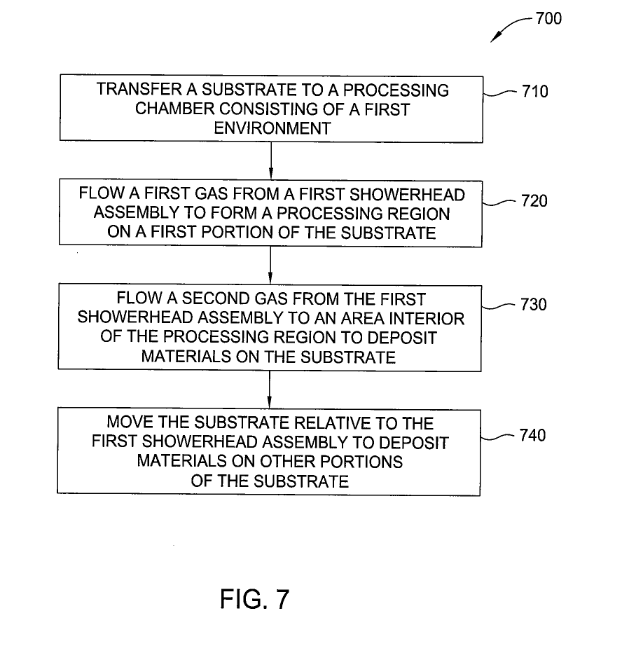

FIG. 7 is a flowchart of one embodiment of a substrate processing method 700. At 710, a substrate, such as the substrate 150₂ is transferred to a processing chamber having an internal volume 115 consisting of a first environment. The first environment includes a first pressure, a first gas composition, a first temperature, and combinations thereof. At 720, a first gas is flowed from a first showerhead assembly, such as showerhead assembly 160A, to form a gas curtain and enclose a processing region, such as processing region 309, on a first portion of the substrate 150₂. The first portion includes a fraction of the length of the substrate 150₂, such as between about ⅛ to about ⅔ of the length of the substrate 150₂. In one embodiment, the area interior of the gas curtain contained in the processing region 309 comprises a second environment that is different than the first environment. The gas curtain provided by the first gas effectively isolates the second environment from the first environment, which enables a reduced volume of process gases flowed to the substrate 150₂. The second environment includes a second pressure, a second gas composition, a second pressure, and combinations thereof that are different than the first pressure, temperature and/or gas composition. At 730, a second gas is flowed from the showerhead assembly 160A to an area interior of the gas curtain within the processing region 309. In one embodiment, the second gas is a reactive gas that forms a first thin film on the substrate 150₂. At 740, the substrate 150₂ is moved relative to the first showerhead assembly 160A to expose other portions of the substrate 150₂ to the second gas.

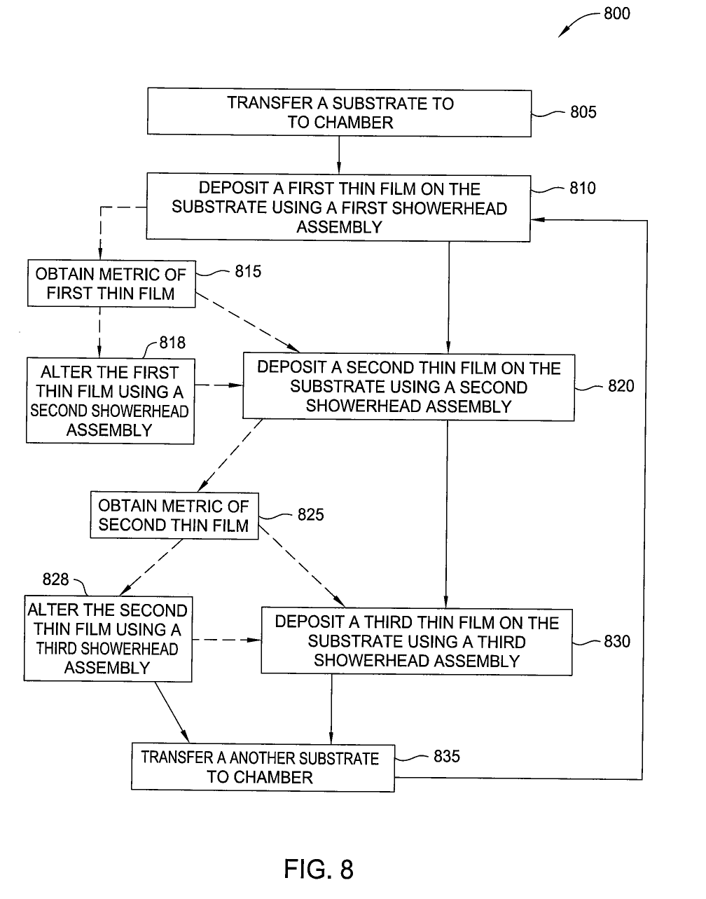

FIG. 8 is a flowchart of another embodiment of a substrate processing method 800. Referring to FIGS. 1-6, a first substrate 150₂ is transferred to the processing chamber 100 at 805. The first substrate 150₂ is caused to move into the processing chamber 100 along a substrate travel path along a plurality of rollers 112. In one example, the substrate 150₂ enters the processing chamber 100 and travels along the substrate travel path in the −X direction. At 810, a first thin film is deposited on the first substrate 150₂ using a first showerhead assembly, such as showerhead assembly 160A. In this embodiment, the first showerhead assembly 160A is configured for a deposition process, such as PECVD, HWCVD or LCVD.

In one embodiment, at 820, a second thin film may be deposited on the first substrate 150₂ by a second showerhead assembly, such as the showerhead assembly 160B. In one embodiment, the second showerhead assembly 160B is configured for a deposition process, such as PECVD, HWCVD or LCVD. Alternatively, prior to the second thin film being deposited on the first substrate 150₂, a metric of the first thin film may be obtained, as shown at 815. The metric may be obtained either ex-situ or in-situ, such as by the at least one inspection device 190. The metric may determine that the first thin film is acceptable and the second thin film is to be deposited at 820. Alternatively, at 818, the metric may indicate a need for altering the first thin film prior to depositing the second thin film. In this example, the second showerhead assembly 160B is provided with an energy emitting device 510 adapted to alter the first thin film by annealing and/or ablation. Subsequent to the alteration of the first thin film, the second thin film may be deposited by an LCVD process by the second showerhead assembly 160B at 820.

After the second thin film has been deposited at 820, a third thin film may be deposited on the first substrate 150₂ at 830 by a third showerhead assembly, such as showerhead assembly 160C. In one embodiment, the third showerhead assembly 160C is configured for a deposition process, such as PECVD, HWCVD or LCVD. Alternatively, prior to the third thin film being deposited on the first substrate 150₂, a metric of the second thin film may be obtained, as shown at 825. The metric may be obtained either ex-situ or in-situ, such as by the at least one inspection device 190. The metric may determine that the second thin film is acceptable and the third thin film is to be deposited at 830. Alternatively, at 828, the metric may indicate a need for altering the first thin film prior to depositing the second thin film. In this example, the third showerhead assembly 160C is provided with a laser source 512 adapted to alter the second thin film by annealing and/or ablation. Subsequent to the alteration of the second thin film, the third thin film may be deposited by an LCVD process by the third showerhead assembly 160C at 830.

Subsequent to the alteration of the second thin film by the third showerhead assembly 160C at 828 and/or deposition of a third thin film by the third showerhead assembly at 830, the first substrate 150₂ may be transferred out of the processing chamber 100 and a second substrate may be transferred into the processing chamber 100, as shown at 835. The method then repeats at 810 on the second substrate utilizing obtaining a metric of the films and/or repair of the films, or alternatively, progressing directly from deposition of the first thin film to deposition of the second and third thin films with out inspection and/or alteration.

While the foregoing is directed to embodiments of the present invention, other and further embodiments of the invention may be devised without departing from the basic scope thereof, and the scope thereof is determined by the claims that follow.

1. An apparatus for forming thin films, comprising:
a chamber defining an interior volume; and
at least two showerhead assemblies movably coupled to the chamber within the interior volume opposing a movable substrate support surface, each of the showerhead assemblies being coupled to an actuator providing movement of the respective showerhead assembly in a first linear direction relative to the movable substrate support surface, each of the showerhead assemblies comprising an inner gas channel and an outer gas channel surrounding and separated from the inner gas channel, each of the inner gas channels and outer gas channels having a plurality of openings formed therein, the openings in the inner gas channels being directed toward the substrate support surface to deliver a first gas, and the openings in the outer gas channel being oriented to direct a second gas toward the substrate support surface and completely enclose the first gas.

2. The apparatus of claim 1, wherein the movable substrate support surface comprises a plurality of rollers coupled to lower portion of the chamber within the interior volume.

3. The apparatus of claim 2, wherein the plurality of rollers are coupled to a motor to move a substrate in a second linear direction relative to the at least two showerhead assemblies.

4. The apparatus of claim 2, wherein the first linear direction is substantially normal to the second linear direction.

5. The apparatus of claim 1, wherein one of the at least two showerhead assemblies is coupled to a radio frequency power source and a matching circuit.

6. The apparatus of claim 1, wherein one of the at least two showerhead assemblies comprises at least one heating filament.

7. The apparatus of claim 1, wherein one of the at least two showerhead assemblies comprises an optical device to emit electromagnetic radiation at a wavelength between about 600 nm and about 1000 nm.

8. The apparatus of claim 1, wherein one of the at least two showerhead assemblies comprises at least two actuators coupled to opposing ends of the showerhead assembly.

9. The apparatus of claim 8, wherein the at least two actuators are controlled independently.

10. The apparatus of claim 1, wherein one of the at least two showerheads is coupled to motor to move the showerhead assembly in a third linear direction, the third linear direction being substantially normal to the first linear direction.

11. The apparatus of claim 1, wherein each of the at least two showerhead assemblies comprise at least two actuators coupled to opposing ends thereof.

12. The apparatus of claim 11, wherein each of the at least two actuators are independently controlled.

13. The apparatus of claim 1, further comprising:
one or more sensors arranged to detect the presence of a substrate disposed on the movable substrate support surface.

14. An apparatus for forming thin films on flexible media, comprising:
a chamber having at least two showerhead assemblies movably coupled to an interior of the chamber, each of the at least two showerhead assemblies being coupled to a first linear motion assembly to move the respective showerhead assemblies in a Z direction, each of the showerhead assemblies comprising an inner gas channel and an outer gas channel surrounding and separated from the inner gas channel, each of the inner gas channels and outer gas channels having a plurality of openings formed therein, the openings in the inner gas channels being directed toward the flexible media to deliver a first gas, and the openings in the outer gas channel being oriented to direct a second gas toward the flexible media and completely surround the first gas; and
a movable substrate support surface disposed within the interior of the chamber in an opposing relationship to the at least two showerhead assemblies, the movable substrate support surface comprising a plurality of rollers to receive and support at least a portion of the flexible media and defining a linear substrate travel path in the X direction to move the flexible media relative to the at least two showerhead assemblies.

15. The apparatus of claim 14, wherein the each linear motion assembly comprises a first actuator and a second actuator coupled to respective ends of each showerhead assembly.

16. The apparatus of claim 15, wherein the first actuator and second actuator are independently controlled.

17. The apparatus of claim 14, wherein one of the at least two showerhead assemblies is coupled to a radio frequency power source and a matching circuit.

18. The apparatus of claim 14, wherein one of the at least two showerhead assemblies comprises at least one filament.

19. The apparatus of claim 14, wherein one of the at least two showerhead assemblies comprises an optical device to emit electromagnetic radiation at a wavelength between about 600 nm and about 1000 nm.

20. The apparatus of claim 14, wherein at least one of the at least two showerhead assemblies is coupled to a second linear motion assembly to move the showerhead assembly in the X direction.

21. A method for processing a substrate, comprising:
transferring a substrate to a processing chamber having an internal volume consisting of a first environment;
flowing a first gas from a perimeter of a first showerhead assembly to form a processing region on a portion of the substrate, the processing region comprising a second environment that is substantially isolated from the first environment;
flowing a second gas from a center of the first showerhead assembly to an area interior of the processing region to deposit a first thin film on the substrate; and
moving the substrate in a first linear direction relative to the first showerhead assembly to deposit the first thin film on other portions of the substrate.

22. The method of claim 21, wherein the first thin film is deposited by a chemical vapor deposition process.

23. The method of claim 22, wherein the chemical vapor deposition process is selected from the group consisting of PECVD, LCVD, HWCVD, or combinations thereof.

24. The method of claim 21, wherein the portion of the substrate consists of a width of the substrate and a fraction of a length of the substrate.

25. The method of claim 21, further comprising:
moving the first showerhead assembly in a second linear direction relative to the substrate.

26. The method of claim 25, wherein second linear direction is the same as the first linear direction.

27. The method of claim 25, wherein second linear direction is normal to the first linear direction.

28. The method of claim 21, further comprising:
depositing a second thin film on the substrate with a second showerhead assembly disposed in the processing chamber.

29. The method of claim 21, further comprising:
annealing the first thin film with a second showerhead assembly disposed in the processing chamber.

30. A method for processing a portion of a substrate, comprising:
transferring a substrate to a processing chamber having a movable support surface adapted to move the first substrate in a first linear direction;
depositing a first thin film on a portion of the substrate with a first showerhead assembly disposed in the processing chamber, the first showerhead assembly movable in a second linear direction that is substantially normal to the first linear direction;
moving the substrate in the first linear direction relative to the first showerhead assembly; and
altering the first thin film with a second showerhead assembly disposed in the processing chamber.

31. The method of claim 30, wherein altering comprises depositing a second thin film on the first thin film.

32. The method of claim 30, wherein altering comprises annealing the first thin film.

33. The method of claim 30, wherein altering comprises ablating a portion of the first thin film.

34. The method of claim 33, further comprising:
depositing a second thin film on the ablated portion of the first thin film.
